(19) United States
(12) Patent Application Publication
(10) Pub. No.: US 2024/0289518 A1
(43) Pub. Date: Aug. 29, 2024

(54) Method for Recognizing Causes of Anomalies in a Physical Product

(71) Applicant: Siemens Aktiengesellschaft, München (DE)

(72) Inventors: Raven Thomas Reisch, München (DE); Matteo Pantano, München (DE); Tobias Hauser, Bubesheim (DE); Daniel Regulin, Geltendorf (DE); Benjamin Samuel Lutz, Erlangen (DE)

(73) Assignee: Siemens Aktiengesellschaft, München (DE)

(21) Appl. No.: 18/686,616

(22) PCT Filed: Jun. 22, 2022
(86) PCT No.: PCT/EP2022/066954

§ 371 Date: Feb. 26, 2024

(30) Foreign Application Priority Data
Aug. 26, 2021 (EP) 21193259.5

(51) Int. Cl. G06F 30/20

(52) U.S. Cl. CPC G06F 30/20

(57) ABSTRACT

Various embodiments of the teachings herein include a method for recognizing causes of anomalies in a physical product during the design, fabrication, and/or service life thereof. An example method includes: creating a semantically linked digital representation of the physical product, the representation including design features and fabrication features of the physical product; transmitting information about anomalies from a quality test to the digital representation and storing said information; and identifying semantic patterns to recognize causes of anomalies using the information, the design features, and/or the fabrication features. The information about anomalies is transmitted in the form of attributes of the product. The attributes contain the location and the time point of the anomaly and machine codes and product regions. The product is assigned location coordinates in a spatial coordinate system for specific time points.

### CROSS-REFERENCE TO RELATED APPLICATIONS

This application is a U.S. National Stage Application of International Application No. PCT/EP2022/066954 filed Jun. 22, 2022, which designates the United States of America, and claims priority to EP Application No. 21193259.5 filed Aug. 26, 2021, the contents of which are hereby incorporated by reference in their entirety.

### TECHNICAL FIELD

The present disclosure relates to manufacturing. Various embodiments of the teachings herein include systems and/or methods for recognizing causes of anomalies in a physical product.

### BACKGROUND

During the lifecycle development of products, i.e. components that are to be manufactured or a plurality of assembled components, a lengthy iterative process takes place between planning (e.g. CAD/CAM) and manufacture/quality control, as a standard process for the creation of the manufactured parts. This process normally involves a plurality of actors (e.g. machines, evaluation software, operators and product developers) providing parameters and design decisions on the basis of their experience and their knowledge in order to satisfy the partial requirements. A comprehensive approach which can integrate and combine the information from all actors is not yet available. As a consequence, seamless transfer of data between the various lifecycle phases is not currently possible, or results in a high level of complexity and synchronization errors. It is often necessary to gather data for the same workpiece more than once along its lifecycle. Furthermore, the knowledge cannot be scaled beyond individual people and is lost when experts change position. The high level of complexity, the lack of scalability in current systems and the loss of knowledge result in high costs in a product lifecycle.

Anomalies during the fabrication of products or components, which anomalies can grow into errors, can be recognized by operating personnel or by means of evaluation software, for example. All the participating actors can react differently in this case, resulting in different evaluations concerning the fabrication process.

### SUMMARY

The teachings of the present disclosure provide methods and/or systems for recognizing an anomaly in a product, which, in comparison with the prior art, are more suitable for the purpose of reducing variations in the quality of a product during both production and servicing over the lifecycle thereof, irrespective of the actors involved. For example, some embodiments include a method for recognizing causes of anomalies in a physical product (2) during the design (4), fabrication (6) and/or service life thereof, comprising: creating a semantically linked digital representation (8) of the physical product (2), comprising the design features (10) and fabrication features (12) thereof, transmitting information (18) about anomalies (16) from a quality test (14) to the digital representation (8) and storing said information (18), and identifying semantic patterns in order to recognize causes of anomalies using the information (18), the design features and/or the fabrication features, wherein the information (18) about anomalies (16) is transmitted in the form of attributes of the product, wherein the attributes contain the location and the time point of the anomaly (16) and the attributes contain machine codes and product regions, wherein a spatial coordinate system (22) is provided in which the product (2) is assigned location coordinates for specific time points.

In some embodiments, the digital representation (8) comprises a knowledge graph (24).

In some embodiments, at least the attributes location and time of the product are placed in a semantic relation by means of the knowledge graph (24).

In some embodiments, an interface (26) is provided via which information (18) about anomalies (16) is transferred into the digital representation (8).

In some embodiments, the interfaces (26) are embodied in the form of HMI interfaces.

In some embodiments, the interface (26) is embodied in the form of a coordinate-dependent marker unit.

In some embodiments, the interface is embodied in the form of a virtual reality tracker.

In some embodiments, calculations for depicting the digital representation (8), in particular the knowledge graph (24), are carried out by means of a cloud computer (28).

In some embodiments, the information is analyzed by means of an edge device (30) and a connection to the cloud computer (28) is established by means of the edge device (30).

In some embodiments, the physical product (2) is created by means of an additive manufacturing method (32).

In some embodiments, the additive manufacturing method (32) takes the form of a wire arc additive manufacturing method or a laser deposition welding method.

As another example, some embodiments include a computer program product which is designed to perform one or more of the methods described herein when executed on a computer.

### BRIEF DESCRIPTION OF THE DRAWINGS

Further embodiments and further features of the teachings herein are described in greater detail with reference to the figures. In this case, features having the same designation but in different embodiment variants in the figures are denoted by the same reference signs. In the drawings:

FIG. 1 shows a schematic sequence of an example method for recognizing causes of anomalies, with pictograms of the relevant individual product lifecycle sections, incorporating teachings of the present disclosure; and

FIG. 2 shows a schematic depiction of a digital representation in the form of a knowledge graph.

### DETAILED DESCRIPTION

Some embodiments of the teachings herein include a method for recognizing causes of anomalies in a physical product during the design, fabrication and/or service life thereof, the method comprising:
creating a semantically linked digital representation 8 of the physical product 2, comprising the design features 10 and fabrication features 12 thereof,
transmitting information 18 about anomalies 16 from a quality test 14 to the digital representation 8 and storing said information 18, and
identifying semantic patterns in order to recognize causes of anomalies using the information 18, the design features and/or the fabrication features.
   Terms that are Used Herein are Defined as Follows:

A digital representation can also be considered as a digital twin of a design and/or manufacturing process of the product. The digital representation in this case can include design activities which are effected by means of a CAD system, for example. It can however also include manufacturing simulations which are effected by means of a CAM method, and the physical manufacture itself.

With regard to the physical manufacture, process data such as process monitoring data from sensors and evaluations thereof, or the insertion of a component holder, or the positioning and sequence of individual subcomponents for the assembly of a product, are then included in the digital representation in this case. The digital representation can be embodied in the form of a knowledge graph, for example, this being used to place items of information about the component in semantic relation to each other. A digital twin in general is again a digital representation of a material or immaterial object or process from the real world in the digital world. Digital twins allow a cross-discipline exchange of data. They are more than pure data in this case, consisting of models of the represented object or process, and can also contain simulations, algorithms and services which describe or influence the properties or behavior of the represented object or process, or offer services relating to these.

Semantic relations: these are understood to include inter alia local relationships, spatial relationships e.g. between a part of the product during the manufacture or a robot arm used for manufacturing. Semantic relations also include causalities such as e.g. the respective coordinate specification of the component relative to a coordinate system at the respective process time point or the amount of energy that is introduced during a specific process time point. A plurality of semantic relations result in semantic linking, which can in turn comprise a semantic pattern if specific semantic links are repeated.

The quality test can take place during the fabrication or after the fabrication of the product during the service life thereof (IEC 62890).

Anomalies are product-related phenomena which deviate from the anticipated and/or simulated quality. Anomalies can grow into an error in the component. They can often be recognized particularly efficiently by humans. Recognized errors are converted into information for the semantic representation.

Design features and fabrication features: design features are e.g. contours and material nature of the product, which both influence the functional properties of the product or component and also affect the fabrication method. The design features are usually created by means of a digital design method such as e.g. CAD, and the resulting data can be provided to the digital representation as information. The design features also have an effect on the fabrication features.

Fabrication features are created by means of e.g. a digital process planning method such as CAM. They are also derived from the digital design features in this case and can again be provided to the digital representation as information. Fabrication features are in particular process data of the manufacturing process. Process data is all the data that arises during the process. This includes the sensor signals and at least some of the process parameter set. The process parameter set comprises all of the technical variables that are applied during the process, e.g. position and speed of a robot arm at a specific time, but in particular machine settings such as e.g. energy input (e.g. in the form of current and voltage) and, using the example of an additive fabrication method, e.g. the distance of a welding torch from the component, a gas flow or an arc length adjustment.

The described methods therefore accompany a product design and a manufacturing method (fabrication method). Information from the product design method, the fabrication method, and the quality test are reprocessed by the methods described herein in the digital representation, and semantic patterns which could result in anomalies and subsequently in defects are traced. Using these semantic patterns, it is possible to draw conclusions in relation to optimization requirements in the individual examined sections of the product design and manufacturing process, and hence in relation to the complete product and service-life cycle, and to indicate improvement recommendations or implement said recommendations automatically in the form of optimization measures (closed-loop control). In particular, the described method can eliminate external interference effects resulting from e.g. specific peculiarities of the process means (e.g. from a specific robot apparatus) but in particular also from human influence (e.g. operating personnel or a design engineer using a CAD program).

In some embodiments, the digital representation comprises a knowledge graph (knowledge bank) which uses a graph-structured data model or topology to integrate the items of information relating to anomalies. Knowledge graphs are suitable for storing linked items of information, such as the attributes of the product (e.g. location, time point, component region, process parameters, causalities), with a semantic relation.

An HMI interface is a human-machine interface and this can be e.g. a conventional input device for a computer such as a keypad or a mouse but can also be embodied in the form of a VR tracker or a trace pen.

Machine code: a machine code is a sequence of instructions which has been created according to the rules of a higher-level programming language and can be executed directly (without further translation) by the processor of a device, e.g. a controller with electronic data processing. G-Code (DIN 66025) is cited as an example of a machine code for industrial controllers such as e.g. Sinumerik. Further examples include special robot programming languages such as KRL (Kuka Robot Language) or RAPID.

A product region, or component region if the product is a component, can also be referred to as a region of interest (ROI). This is not just a singular point, but a volume region which, in relation to the process parameter, is causally associated with a point, e.g. an anomaly. In the case of an additively manufactured component, this could be e.g. a point which is adjacent to the detected anomaly but is in a subsequent deposition layer, said layer being deposited in a manner which is temporally and possibly also locally offset. Other process parameters may already exist for this deposition layer. The anomaly and the described point nonetheless belong to an ROI.

Edge device: an edge device is a device which provides a node point between two networks, e.g. between the described machine network and the sensor network, or between the sensor network and the internet. In this case, the edge device can take the form of a controller which has a connection to a further network.

Cloud computer: a cloud is basically a computing unit and/or storage unit which is remote from the location of the claimed method and to which the digital representation is connected e.g. via an edge device for the purpose of data transmission. The cloud in this case can comprise a cloud computer which has more processing power than the locally available computers, e.g. the edge devices or controllers. Accordingly, complex calculations can be performed more quickly and efficiently, and more economically, on the cloud computer. The digital representation can therefore be allocated entirely or partly to a cloud. The results obtained there can be reflected back to a local computing unit via data connections.

In some embodiments, the information about anomalies is transmitted in the form of attributes of the product, said attributes containing the location and time point of the anomaly. It is also appropriate for the attributes to contain machine codes and product regions. Practice has shown that in particular the attributes time, location, product region and machine code are particularly suitable for inclusion in the digital representation and for processing by same. On the basis of this information, it is possible for semantic patterns of occurring anomalies to be derived particularly effectively.

A spatial coordinate system may be particularly advantageous, the product being assigned location coordinates for specific time points.

In some embodiments, the digital representation comprises a knowledge graph, the semantic patterns being derived on the basis thereof. By means of the knowledge graph, at least the attributes location and time of the product are placed in a semantic relation.

It is moreover appropriate to provide an interface via which information about anomalies is transferred into the digital representation. The interfaces may comprise HMI interfaces. These can be a keypad or an input device by means of which e.g. the product design takes place or the process parameters are adapted. Furthermore, the HMI interface can also be embodied in the form of a coordinate-dependent marker unit. This is appropriate for the quality test in particular. The embodiment of the interface can take the form of a virtual reality tracker, for example.

In some embodiments, the method includes performing calculations for depicting the digital representation, in particular the knowledge graph, by means of a cloud computer. The advantage here is then being able to rely on powerful computers which need not necessarily be arranged at the location where the products are fabricated. This saves investment costs, since the computing power on site can be reduced to an optimal level.

Provision can be made on site for e.g. an edge device, which establishes the connection to the cloud computer and by means of which the information is analyzed and transmitted. The edge device can also be integrated into a process controller.

The described methods may be suitable for recognizing anomalies in a wide variety of manufacturing methods. The physical product can consist of an assembly of various individual products in this case (assembly method), but the described method can also concern the manufacturing process of an individual component. It may be suitable for monitoring an additive manufacturing method such as e.g. a wire arc additive manufacturing method or a laser deposition welding method.

Some embodiments include a computer program product which is designed to carry out one or more of the methods described herein when executed on a computer.

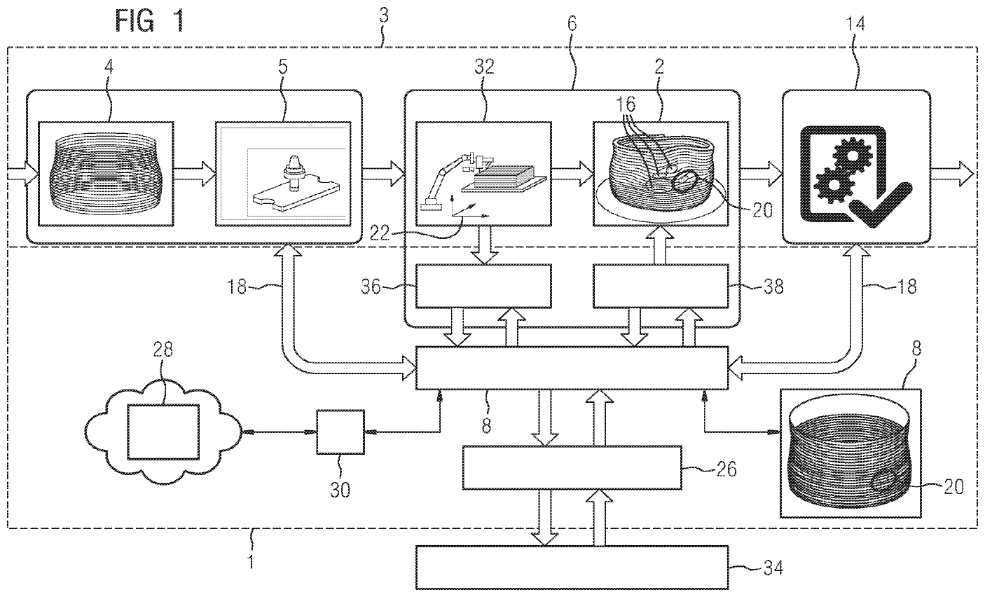

The diagram in FIG. 1 shows both a schematic sequence of a method for recognizing causes of anomalies 1 and a product cycle 3 of a physical product 2. In this case, the selected individual steps of the product cycle 3 are merely exemplary and can be replaced by other applications. The diagram shows the product cycle 3 of the physical product 2, extending from the product design method 4 through to quality control 14. This cycle 3 can be extended further, possibly also including e.g. quality testing of the product 2 throughout its entire service life.

At the start of the product cycle is a design method 4, e.g. in the form of a CAD method. The physical product 2 is usually devised by a person here. In this case, the person in the form of the designer incorporates their own personal ideas of how the product is best designed in technical terms. The actual implementation of the design can however lead to technical disadvantages during the application of the product 2 or during the fabrication thereof. The further step following thereupon is usually the conversion of the CAD data into a computer-aided manufacturing program (CAM) 5. This manufacturing program 5 converts the design specifications into process parameters for the manufacture of the physical product 2.

The product is therefore designed in CAD (e.g. Siemens NX) and the process planning takes place in CAM (likewise e.g. Siemens NX). For the purpose of the manufacturing process, the digital process planning can be parsed into machine code (G-Code) that can be read by a Siemens Sinumerik controller/CNC controller which controls the manufacturing process.

This is followed by manufacture 6 of the physical product itself. The present example depicts a robot-controlled manufacture of an additively fabricated component which constitutes the product 2. This depiction has been selected purely by way of example here. It can also relate to e.g. a casting process or an extrusion process for a component, which is then referred to as a physical product 2. It is also possible in principle to manufacture an assembled product 2 from various previously existing components. The method described in the following is applicable to any desired fabrication method.

In the next step, the manufactured physical product 2 is depicted in FIG. 1 in the form of an additively fabricated component. It is possible here to recognize an anomaly 16 which has arisen in a component region 20. The anomaly 16 is initially a mere deviation from an optimal state as planned by the CAM in the production process. An anomaly 16 need not itself represent an error, but can nonetheless develop to become an error as the process continues unless it is evaluated and/or countermeasures are introduced. The introduction of countermeasures during the process is also referred to as closed-loop control 38.

As part of the processes described, in the context of quality testing 14 and/or process control 36, operating personnel 34 are often appointed to detect and mark anomalies 16 in resulting physical products 2. In principle, this can also be effected by means of a specific automated quality assurance, e.g. with the aid of special cameras (not shown here) and evaluation software. Operating personnel 34 are nonetheless still able to recognize anomalies in complex processes more effectively than is possible using technical apparatuses. However, the threshold for recognizing anomalies 16 or the type of input via an interface 26 may be different for different operating personnel 34. This lack of reliability and limited reproducibility of response by operating personnel 34 nonetheless hampers the automated process sequence.

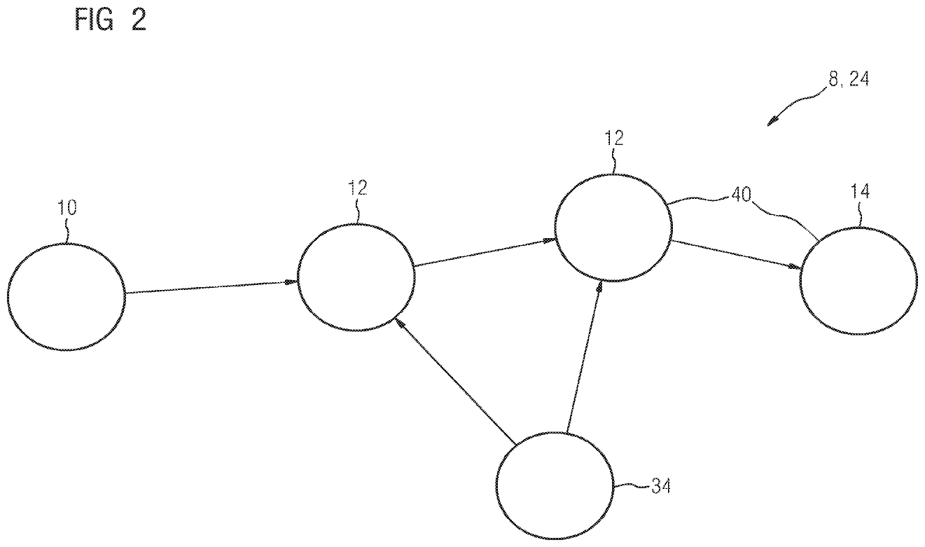

A method 1 for recognizing causes of anomalies is therefore provided, said method being able to evaluate various items of information 18 from the process cycle 3. In order to achieve this, a digital representation 8 of the product 2 is created, including the design and fabrication features thereof. Such a digital representation 8 can also be referred to as a digital twin. The digital representation in this case includes a so-called knowledge graph 24, which includes semantic links between the items of information 18 that are fed into the digital representation 8. Process parameters that have been recorded, including sensor data, are also incorporated into the digital representation 8 as items of information 18 and continuously synchronized. From these semantic links, which are depicted by way of example in FIG. 2, semantic patterns can be computed by means of an algorithm. These semantic patterns are then used to recognize causes of anomalies.

Causes of anomalies here can be errors in the design, for example, but anomalies 16 can also be caused by errors in the process management, which in turn may be caused by the CAM method. Even the marking of anomalies 16 by an operator 34, who monitors the process visually and marks the anomaly 16 using e.g. a coordinate-dependent marker unit (considered as an interface 26, e.g. a laser pointer or a trace pen) and thereby incorporates information 18 about the anomaly 16 into the digital representation 8, can again constitute a cause of anomalies in the case of different handling. This is because different operating personnel 34 might handle and operate the marker unit differently.

A multiplicity of different items of information 18 about anomalies 16 are therefore incorporated and stored in the digital representation 8. These items of information 18 may contain either a typical human response relating to an individual and/or deviations from a technical standard response. Either of these different causes can disrupt the optimal product cycle and lead to anomalies 16 and subsequently to errors in the product 2.

By means of the knowledge graph 24 in the digital representation 8, evaluations are performed by means of complex algorithms in order to determine possible semantic patterns which could lead to anomalies. To this end, design and manufacturing data from the CAD and/or CAM system are also stored as information in the knowledge graph 24 and available for the evaluation of semantic patterns. Such semantic patterns can reveal e.g. peculiarities in the design which correspond to specific process parameters and lead to anomalies in this way. Furthermore, specific characteristics of operating personnel 34 in the context of quality testing 14, for example, can likewise lead to changes in the information 18 about anomalies, this in turn influencing the process management in the form of feedback. The storage of information about critical operating personnel 34 and their response patterns in relation to the quality test can be stored in the knowledge graph 24 and provide a semantic pattern during the evaluation of information, the result of which can lead to changes in the process management.

The identification of semantic patterns within a knowledge graph 24 by means of the described algorithms can demand a significant amount of computing power. Such large amounts of computing power are often not available in factory buildings in the immediate environment of production plant, or can only be installed there uneconomically due to the cost thereof. For this reason, it is appropriate to use a cloud computer 28 for the evaluation of the knowledge graph 24 and to identify semantic patterns. This cloud computer 28 can be connected to the manufacturing process or the product cycle 3 via an edge device 30, for example. The edge device 30 in this case can be e.g. part of a process controller such as a Sinumerik Edge, for example.

The described method depicts the product 2 by means of four main attributes, namely the time, the location, the component region 20 (region of interest—ROI) and a machine code (e.g. G-Code), and by means of integrating contextual information that is provided by specific locations, said attributes can be connected together. Use is preferably made here of a coordinate system 22 by means of which the position of the product 2 and the position of manufacturing means such as a robot arm can be consistently specified.

The networking between the various domains (time, location, machine code, etc.) is achieved as a result of creating the digital representation 8, a digital twin of the product 2 being produced, with the aid of the described knowledge graph 24. By means of this methodology, the semantics for each point of the part are correlated with the four attributes cited above, whereby a flexible relationship between knowledge from the different domains is established. The knowledge graph 24 is created using the input/process/output entity model for nodes 40. In the case of an additive manufacturing method, for example, each weld point therefore takes as an input the specific locations of the adjacent weld point, these being referred to as ROI (a collection of weld points) and process parameters (e.g. geode, time, specific location, maximum temperature, etc.). The operator 34 can interact with the knowledge graph 24 at this point. Domain expertise interfaces may be used for this purpose. The interfaces (HMI) can be many and diverse, depending primarily on the operator 34 and the process that is monitored. These interfaces 26 communicate with the digital representation, assign attributes to the product region 20 (ROI) and thus improve the knowledge graph 24. An automatic correlation between the various domains and the various phases in the process cycle 3 by means of the knowledge graph 24 allows the optimization of each process step (CAD, CAM, process parameters, application).

By virtue of the described methods and systems, it is also possible subsequently to associate failures of the product, during the service life thereof, with specific process parameters and process situations, including relevant response patterns of operating personnel 34. A cost reduction due to reduced expenditure of effort is also achieved thereby, since information can be integrated automatically and correlations can be derived automatically by means of data mining in the knowledge graph.

### LIST OF REFERENCE SIGNS

1 Method for recognizing causes of anomalies
2 Physical product
3 Product cycles
4 Design method
5 Computer-aided manufacturing program
6 Fabrication method
8 Digital representation
10 Design features
12 Fabrication features
14 Quality test
16 Anomalies
18 Information
20 Product region
22 Coordinate system
24 Knowledge graph
26 Interface
28 Cloud computer
30 Edge device
32 Additive manufacturing method
34 Operator
36 Process control
38 Closed-loop control
40 Node knowledge graph

What is claimed is:

1. A method for recognizing causes of anomalies in a physical product during the design, fabrication, and/or service life thereof, the method comprising:
creating a semantically linked digital representation of the physical product, the representation including design features and fabrication features of the physical product;
transmitting information about anomalies from a quality test to the digital representation and storing said information; and
identifying semantic patterns to recognize causes of anomalies using the information, the design features, and/or the fabrication features;
wherein the information about anomalies is transmitted in the form of attributes of the product;
wherein the attributes contain the location and the time point of the anomaly and machine codes and product regions; and
wherein the product is assigned location coordinates in a spatial coordinate system for specific time points.

2. The method as claimed in claim 1, wherein the digital representation comprises a knowledge graph.

3. The method as claimed in claim 1, wherein the knowledge graph places the attributes location and time of the product in a semantic relation.

4. The method as claimed in claim 1, wherein an interface transfers information about anomalies into the digital representation.

5. The method as claimed in claim 4, wherein the interfaces comprises HMI interfaces.

6. The method as claimed in claim 4, wherein the interface comprises a coordinate-dependent marker unit.

7. The method as claimed in claim 4, wherein the interface comprises a virtual reality tracker.

8. The method as claimed in claim 1, further comprising conducting the calculations for depicting the digital representation with a cloud computer.

9. The method as claimed in claim 8, further comprising:
analysing the information using an edge device; and
connecting to the cloud computer using the edge device.

10. The method as claimed in claim 1, further comprising manufacturing the physical product with an additive manufacturing method.

11. The method as claimed in claim 10, wherein the additive manufacturing method includes a wire arc additive manufacturing method or a laser deposition welding method.

12. (canceled)
